(19) United States
(12) Patent Application Publication
(10) Pub. No.: US 2026/0290460 A1
(43) Pub. Date: Sep. 24, 2026

(54) APPARATUS WITH OPERATIONAL STATE CONTROL MECHANISM AND METHODS FOR OPERATING THE SAME

(71) Applicant: Micron Technology, Inc., Boise, ID (US)

(72) Inventors: Nikhil Garg, Hyderabad (IN); Amiya Banerjee, Bangalore (IN); Neha Dhiman, Delhi (IN); Sriram Viswanathan, Hyderabad (IN); Milind Giradkar, Nagppur (IN)

(21) Appl. No.: 19/540,419

(22) Filed: Feb. 13, 2026

Related U.S. Application Data
(60) Provisional application No. 63/773,854, filed on Mar. 18, 2025.

(51) Int. Cl. G11C 16/10

(52) U.S. Cl. CPC G11C 16/10

(57) ABSTRACT

Methods, apparatuses and systems related to dynamically adjusting a variable ganging size for a ganged reset read utilized in a transient scan. The transient scan may implement memory operations at memory cells to transition the memory cells from a stable state to a transient state or to maintain the memory cells in the transient state. The variable ganging size may be dynamically adjusted according to real-time operating parameters.

### CROSS-REFERENCE TO RELATED APPLICATIONS

The present application claims priority to U.S. Provisional Patent Application No. 63/773,854, filed Mar. 18, 2025, the disclosure of which is incorporated herein by reference in its entirety.

### TECHNICAL FIELD

The disclosed embodiments relate to devices, and, in particular, to semiconductor memory devices with processing level calibration mechanisms and methods for operating the same.

### BACKGROUND

Memory systems can employ memory devices to store and access information. The memory devices can include volatile memory devices, non-volatile memory devices (e.g., flash memory employing “NAND” technology or logic gates, “NOR” technology or logic gates, or a combination thereof), or a combination device. The memory devices utilize electrical energy, along with corresponding threshold levels or processing/reading voltage levels, to store and access data. Conventional semiconductor devices have inherent physical characteristics that introduce errors with respect to data storage and access.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure.

FIG. 1 is a block diagram of a computing system in accordance with an embodiment of the present technology.

FIG. 2 a flow diagram illustrating an example method of operating an apparatus in accordance with an embodiment of the present technology.

FIG. 3 is a schematic view of a system that includes an apparatus in accordance with an embodiment of the present technology.

### DETAILED DESCRIPTION

As described in greater detail below, the technology disclosed herein relates to an apparatus, such as memory systems, systems with memory devices, related methods, etc., for controlling or managing operational state of the apparatus. For context, semiconductor memory devices (e.g., NAND devices) can inherently have a stable state at rest and a transient state following electric excitation (e.g., memory operations). As an illustrative example, a NAND block can transition from a stable state for the threshold voltage (Vt) to a transient state for the Vt within a relatively short window (e.g., less than a second such as 10, 20, 30 milliseconds or more) after initiation of a read/program/verify operation. Following the memory operation, the NAND block can remain in the transient state for a longer window (e.g., tens of minutes). In performing the memory operations, the stable state may be more prone to introducing errors in comparison to the transient state. Stated differently, read operations implemented during the stable state can have a higher likelihood of invoking read error handling and a higher Raw Bit Error Rate (RBER).

To maintain the memory devices in the transient state and reduce the RBER and the read error handling, embodiments of the technology described herein can include an operational state control mechanism. The operational state control mechanism can include hardware, software, firmware, or a combination thereof configured to implement a set of memory operations, such as a scan or a set of read operations, configured to transition the memory circuits (e.g., NAND blocks) into the transient states and maintain them in the transient states. For example, the operational state control mechanism can implement a scan (e.g., a transient Vt (TVT) scan) that performs read operations according to or within a predetermined period without strobing for data. The operational state control mechanism can implement the reads without strobing and/or without transferring the data.

The operational state control mechanism can use a set of grouped reset reads that enables access to multiple circuits, such as per groupings of blocks and/or across planes. With the ganged multiple reads, the operational state control mechanism can reduce the frequency of the TVT scan to maintain the memory circuits in the transient states. The operational state control mechanism can dynamically adjust or vary a number of circuits (e.g., memory block grouping size) according to real-time conditions. For example, the operational state control mechanism can dynamically adjust a variable size of the grouped reset reads according to a phase in the power-on sequence, a current or a predicted workload, a data/charge retention measure (e.g., a program/erase (PE) count, a device age, etc.), an operating condition (e.g., device temperature), or a combination thereof. In some embodiments, the operational state control mechanism can additionally or alternatively adjust a scan frequency for the TVT scan according to one or more of the real-time parameters.

The operational state control mechanism using the dynamically controlled variable size and/or the scan frequency can provide increase efficiency in transitioning the memory circuits into and maintaining them in the transient state. The operational state control mechanism can provide the quality of service (QoS) performance by reducing a time necessary to reach an operational state, such as a time to performance (TTP) phase during or following a power-on reset. Further, the operational state control mechanism can reduce power consumption for the memory device by ensuring sufficient power bandwidth remains available for other features/operations. Moreover, the operational state control mechanism can adapt the resources necessary or consumed for the TVT according to the real-time conditions.

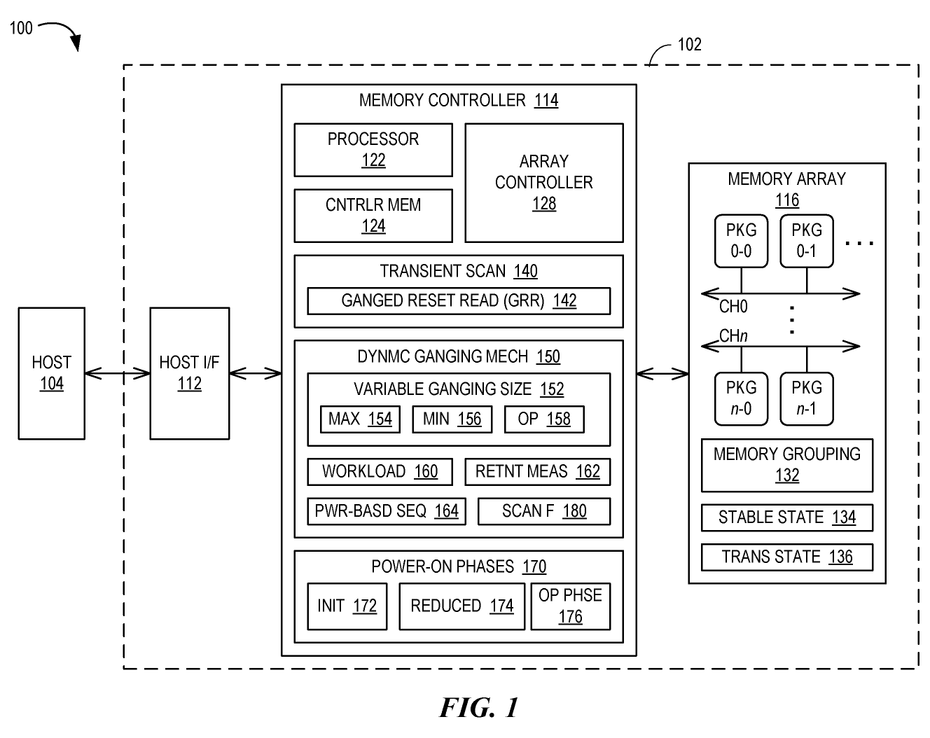

FIG. 1 is a block diagram of a computing system 100 in accordance with an embodiment of the present technology. The computing system 100 can include a personal computing device/system, a mobile device (e.g., a mobile/smart phone), a wearable device, an enterprise device, a server, a mainframe, or the like. The computing system 100 can include a memory system or subsystem 102 coupled to a host device 104. The host device 104 can include one or more processors that can write data to and/or read data from the memory system 102. For example, the host device 104 can include a central processing unit (CPU) controlling the operation of the computing system 100.

The memory system 102 can include circuitry configured to store data (via, e.g., write operations) and provide access to stored data (via, e.g., read operations). For example, the memory system 102 can include a persistent or non-volatile data storage system, such as a NAND-based Flash drive system or the like. In some embodiments, the memory system 102 can include a host interface 112 (e.g., buffers, transmitters, receivers, and/or the like) configured to facilitate communications with the host device 104. For example, the host interface 112 can be configured to support one or more host interconnect schemes, such as Universal Serial Bus (USB), Peripheral Component Interconnect (PCI), Serial AT Attachment (SATA), Universal Flash Storage (USF) protocol, or the like. The host interface 112 can receive commands, addresses, data (e.g., write data), and/or other information from the host device 104. The host interface 112 can also send data (e.g., read data) and/or other information to the host device 104.

The memory system 102 can further include a memory controller 114 and a memory array 116. The memory array 116 can include memory cells that are configured to store a unit of information. For example, the memory array 116 can include NAND dies or packages. The memory controller 114 can be configured to control the overall operation of the memory system 102, including the operations of the memory array 116.

In some embodiments, the memory array 116 can include a set of storage devices or packages. Each of the storage devices can include a set of memory cells that each store data in a charge storage structure. The memory cells can include, for example, floating gate, charge trap, phase change, ferroelectric, magnetoresistive, and/or other suitable storage elements configured to store data persistently or semi-persistently. The memory cells can be one-transistor memory cells that can be programmed to a target state to represent information. For instance, electric charge can be placed on, or removed from, the charge storage structure (e.g., the charge trap or the floating gate) of the memory cell to program the cell to a particular data state. The stored charge on the charge storage structure of the memory cell can indicate a Vt of the cell. For example, a SLC can be programmed to a targeted one of two different data states, which can be represented by the binary units 1 or 0. Also, some flash memory cells can be programmed to a targeted one of more than two data states. Multi-level cells (MLCs) may be programmed to any one of four data states (e.g., represented by the binary 00, 01, 10, 11) to store two bits of data. Similarly, triple-level cells (TLCs) may be programmed to one of eight (i.e., 2³) data states to store three bits of data, and quadruple-level cells (QLCs) may be programmed to one of 16 (i.e., 2⁴) data states to store four bits of data.

Such memory cells may be arranged in rows (e.g., each corresponding to a word line) and columns (e.g., each corresponding to a bit line). The arrangements can further correspond to different groupings 132 for the memory cells. For example, the memory groupings 132 can include memory pages arranged according to word line. Also, the memory groupings 132 can include memory blocks. In operation, the data can be written or otherwise programmed (e.g., erased) with regards to the various memory regions of the memory array 116, such as by writing to groups of pages and/or memory blocks 132. In NAND-based memory, a write operation often includes programming the memory cells in selected memory pages with specific data values (e.g., a string of data bits having a value of either logic 0 or logic 1). An erase operation is similar to a write operation, except that the erase operation re-programs an entire memory block or multiple memory blocks to the same data state (e.g., logic 0).

The memory cells, such as the memory blocks, can be at a stable state 134 with respect to storage and/or access functionalities. The stable state 134 can correspond to a default or a resting physical state for the memory cells/blocks. When the memory cells/blocks are excited, such as a result of one or more memory operations (e.g., read/program/verify operations), the memory cells/blocks can transition to a transient state 136 (e.g., a transient Vt state). For example, the Vt of the charge storage circuits can change and lower the RBER for a predictable duration following the memory operation.

As described above, the memory system controller 114 can be configured to control the operations of the memory array 116. The memory system controller 114 can include a processor 122, such as a special purpose logic circuitry (e.g., a field programmable gate array (FPGA), an application specific integrated circuit (ASIC), etc.), a microprocessor, or other suitable processor. The processor 122 can execute instructions encoded in hardware, firmware, and/or software (e.g., instructions stored in controller embedded memory 124 to execute various processes, logic flows, and routines for controlling operation of the memory system 102 and/or the memory array 116.

Further, the memory system controller 114 can further include an array controller 128 that controls or oversees detailed or targeted aspects of operating the memory array 116. For example, the array controller 128 can provide a communication interface between the processor 122 and the memory array 116 (e.g., the components therein). The array controller 128 can function as a multiplexer/demultiplexer, such as for handling transport of data along serial connection to flash devices in the memory array 116.

In controlling the operations of the memory system 102, the memory system controller 114 (via, e.g., the processor 122, the embedded memory 124, and/or the array controller 128) can implement a Flash Translation Layer (FTL). The FTL can include a set of functions or operations that provide translations for the memory array 116 (e.g., the Flash devices therein). For example, the FTL can include the logical-physical address translation, such as by providing the mapping between virtual or logical addresses used by the operating system to the corresponding physical addresses that identify the Flash device and the location therein (e.g., the layer, the page, the block, the row, the column, etc.). Also, the FTL can include a garbage collection function that extracts useful data from partially filed units (e.g., memory blocks) and combines them to a smaller set of memory units. The FTL can include other functions, such as wear-leveling, bad block management, concurrency (e.g., handling concurrent events), page allocation, error correction code (e.g., error recovery), or the like.

The memory system 102 can include an operational state control mechanism configured to transition the memory array 116 into the transient state 136 and maintain the memory array 116 in the transient state 136. The operational state control mechanism can include hardware, software, firmware, or a combination thereof implemented through the memory controller 114 (e.g., using the processor 122 and the embedded memory 124 therein). The operation state control mechanism can be configured to perform transient scans 140 that scans or reads the memory array 116. As a result, the performed read operations can cause the memory arrays 116 to transition into and/or remain in the transition state 136 for a period of time (e.g., ten minutes or more).

In performing the transient scan 140, the operational state control mechanism can utilize a grouped reset reads 142. The grouped reset reads 142 can be configured to performed multiple read operations or read data from one or more locations. The grouped reset reads 142 can be configured to perform a read operation on one or more blocks within the system without strobing for the data and/or without transferring the data. For example, the grouped reset reads 142 can perform the read operation to 1, 4, 8, 16, 32, 64, or more blocks per plane. As an illustrative example, with 6 planes on a logic unit number (LUN) and up to 64 blocks per plane for the grouped reset reads 142, up to 384 blocks can be addressed per the grouped reset reads 142. Additionally, the grouped reset reads 142 can be permissible on bad blocks.

The operational state control mechanism can further include a dynamic ganging mechanism 150 configured to adjust and vary a variable ganging size 152 according to current or real-time parameters. The variable ganging size 152 can include a number of circuits (e.g., memory blocks) targeted for reset read with one command or scan. In other words, during each implementation of the transient scan 140, the grouped reset reads 142 can implement a reset read on a number of blocks matching the variable ganging size 152.

The variable ganging size 152 can have two or more preset value, such as a maximum 154, a minimum 156, an operational default 158, or a combination thereof. In some embodiments, the minimum 156 can be ten or less (e.g., one), and the maximum 154 can be a predetermined number that corresponds to a size of the array 116, the die/package within the array, the number of blocks within a plane, etc. The operational default 158 can include a predetermined number between the minimum 156 and the maximum 154. As an illustrative example, the minimum 156 can be preset to one, the maximum 154 can be preset to 64, and the operational default 158 can be set to two, four, or eight.

In varying the variable ganging size 152, the dynamic ganging mechanism 150 use a variety of real-time parameters as inputs to (1) select the maximum 154, the minimum 156, and/or the preset operational default 158 as the variable ganging size 152 and/or (2) dynamically compute or adjust the variable ganging size 152 (e.g., from the preset operational default 158). Some example inputs can include a workload measure 160, a retention measure 162, a power-based sequence 164, and/or the like.

The workload measure 160 can represent a pattern, an amount, a frequency of memory operations within a given time or an estimate/prediction of such pattern. For example, the workload measure 160 can include idle, active stead state, sequential, dynamic, transient, and the like. Also, the workload 160 can be application-specific and/or function-specific (e.g., web search, sorting, internal housekeeping, etc.). The computing system 100 and/or the memory system 102 can include functions that recognize the current workload 160 and/or predict the upcoming workload based on the current pattern.

The dynamic ganging mechanism 150 can adjust the variable ganging size 152 according to the workload 160. For example, the dynamic ganging mechanism 150 can decrease the variable ganging size 152 by a predetermined magnitude or set the value to the minimum 156 (e.g., one block at a time) when the workload 160 is idle.

The dynamic ganging mechanism 150 can adjust the variable ganging size 152 according to the retention measure 162 that represents the ability or the capacity of the memory cells/blocks to accurately store, retain, and recall the stored data value. Stated differently, the retention measure 162 can represent the capability of the memory cells to retain the stored charges over time. Some examples of the retention measure 162 can include program/erase (P/E) cycle count, current temperature (e.g., the temperature at the time of read), temperature at the time of writing the data, age of the memory array, etc. As an illustrative example, the dynamic ganging mechanism 150 can increase the variable gaging size 152, such as by increasing by a predetermined increment from the current value or the default operational size 158, when the temperature of the memory system 102 is higher than a targeted operating range. Accordingly, the dynamic ganging mechanism 150 can account for the worsened retentivity of the data as caused by the increased temperature. Likewise, the dynamic ganging mechanism 150 can increase the variable gaging size 152 as the device ages, such as by incrementing the grouping size whenever the P/E cycle count increases over the next threshold (e.g., every n hundred or thousand P/E cycles). Similarly, the dynamic ganging mechanism 150 can increase the variable gaging size 152 to account for the decrease in retentivity as caused by the device usage/age or other environmental factors.

The power-based sequence 164 can include a sequence of values for the variable ganging size 152 that change according to a power-on reset sequence. During the power-on reset sequence, such as following a power-off event and a power-on event, the memory system 102 can cycle through a set of power on phases 170. The power-on phases 170 can include an initial phase 172, a reduced functionality phase 174, and an operating phase 176. The initial phase 172 can represent a duration immediately following the power-on event an up to the point where the memory system 102 becomes operational, such as by being able to respond to read commands. During the initial phase, the memory system can perform open block and erased-page checks. In some embodiments, the initial state 172 can be referenced as a time to ready (TTR) phase.

The reduced functionality phase 174 can follow the initial phase 172 and last until the drive meets all performance and QoS requirements. The reduced functionality phase 174 can last in the order of minutes (e.g., a few minutes, such as less than 10 minutes). The reduced functionality phase 174 can correspond to a period of reduced performance for the memory system 102. In other words, during the reduced functionality phase 174, the memory system 102 can process the user commands but slower or with more errors than the targeted metrics. The reduced performance can be attributed to the memory circuits being in the stable state 134 and not the transient state 136 following the power-on event. In some embodiments, the reduced functionality phase 174 can be referred to as a time to performance (TTP) phase.

The operational phase 176 can follow the reduced functionality phase 174. The operational phase 176 can represent the memory system 102 reaching the targeted performance and QoS requirements. Stated differently, the operational phase 176 is when the memory system 102 can complete the memory operations within a desired timing and with the targeted error performance. The operational phase 176 can correspond to the memory groupings 132 being in or maintained in the transient state 136 instead of the stable state 134.

Based on the characteristics of the different phases, the memory system 102 can perform an initial instance of the transient scan 140 during the reduced functionality phase 174 (e.g., right after the initial phase 172 or as soon as the device can perform reads), and the operational phase 176 can correspond to completing the initial transient scan 140. The memory system 102 can aim to reduce the reduced functionality phase 174 and reach the operational phase 176 quicker. To do so, the power-based sequence 164 can include utilizing the maximum 154 for the variable ganging size 152 during the initial transient scan 140.

However, in using the transient scan 140 to maintain the memory grouping 132 in the transient state 136 during/throughout the operational phase 176, using the maximum 154 for such grouped reset reads 142 can utilize overly large amounts of resources. Such large-scale reads can effectively lock up the corresponding blocks, thereby rendering such blocks inaccessible to the host 104 during the scan. Accordingly, the power-based sequence 164 can include transitioning the variable ganging size 152 from the maximum 154 to the default operational size 158 (e.g., four blocks) after completing the initial instance of the transient scan 140. Thus, the dynamic ganging mechanism 150 can dynamically adjust the variable ganging size to shorten the reduced functionality phase 174 while maintaining the flexibility and responsiveness during the operational phase 176.

In some embodiments, the dynamic ganging mechanism 150 can be configured to adjust a scanning frequency 180 in addition to or instead of the variable ganging size 152. The scanning frequency 180 can represent an upper threshold of time before refreshing a memory block. The scanning frequency 180 can correspond to the timing of performing the refresh reads in order to maintain the memory groupings 132 in the transient state 136 during the operational phase 176. The dynamic ganging mechanism 150 can be configured to adjust the scanning frequency 180 similarly as described for the variable ganging size 152. For example, the dynamic ganging mechanism 150 can increase the scanning frequency 180 (e.g., shorten the durations between refresh reads) for the idle workload and/or as the retentivity measure 162 worsens due to P/E cycle increase or increased temperature.

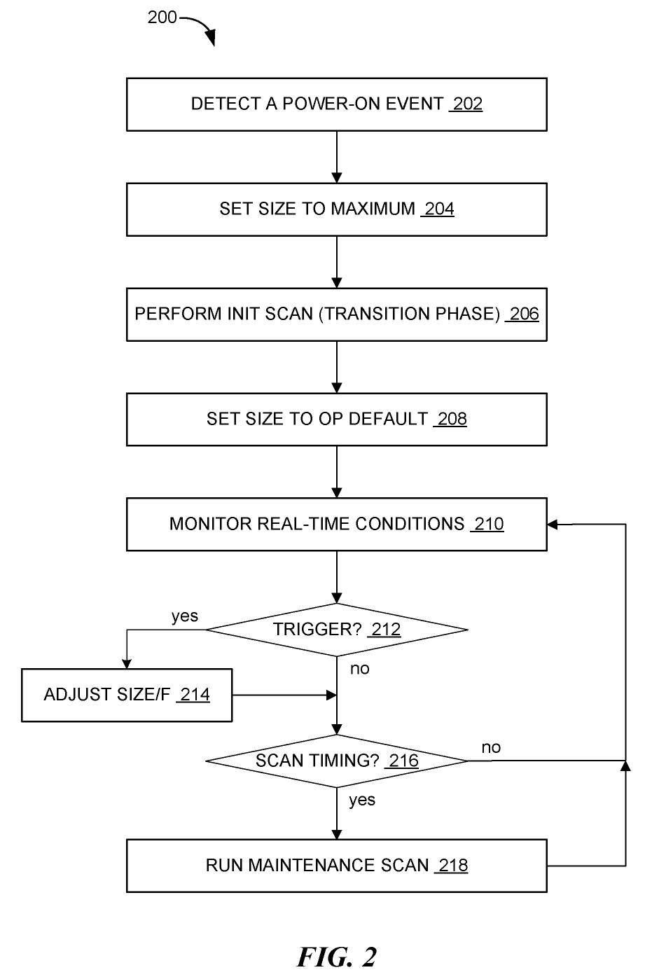

FIG. 2 a flow diagram illustrating an example method 200 of operating an apparatus (e.g., the memory system 102 of FIG. 1, the processor 122 of FIG. 1) in accordance with an embodiment of the present technology. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. The method 200 can correspond to implementing the transient scan 140 of FIG. 1 with the dynamic ganging mechanism 150 of FIG. 1. For example, the method 200 can correspond to dynamically adjusting the variable ganging size 152 of FIG. 1 for the grouped reset reads 142 of FIG. 1 according to real-time conditions.

Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At block 202, the apparatus can detect a power-on event. The power-on event can be detected based on power becoming available to the memory system 102. The apparatus can detect the power-on event as a part of a boot up sequence. As a part of the power-on event, the apparatus can initiate the dynamic ganging mechanism 150. The detection of the power-on event and the initiation of the dynamic ganging mechanism 150 can correspond to the occurrence and/or the end of the initial phase 172 of FIG. 1.

At block 204, the apparatus can set the variable ganging size 152 to the maximum 154 of FIG. 1. For example, the apparatus can proceed through the power-on sequence 170 of FIG. 1, and the dynamic ganging mechanism 150 can follow the power-on sequence 170 of FIG. 1. In following the power-on sequence 170, the dynamic ganging mechanism 150 can prepare for the reduced phase 174 of FIG. 1 and/or the initial instance of the transient scan 140 by setting the variable ganging size 152 to the maximum 154.

At block 206, the apparatus can perform the initial scan, which can correspond to the first implementation of the transient scan 140 following the power-on event. The apparatus can perform the initial scan using the maximum 154 for the variable ganging size 152. For example, the memory system 102 can perform the grouped reset reads 142 of FIG. 1 using the preset maximum number of blocks per plane. Accordingly, the memory device 102 can transition the memory array 116 of FIG. 1 from the reduced performance phase 174 of FIG. 1 to the operational phase 176 of FIG. 1 upon completing the initial scan.

After completing the initial scan, the apparatus can decrease the variable ganging size, as shown in block 208. For example, the apparatus can use the dynamic ganging mechanism 150 to follow the power-on sequence 170 and set the variable ganging size 152 to a lower number, such as the default operational size 158 of FIG. 1. The default operational size 158 can serve as the basis for the subsequent scans used to maintain the memory array 116 in the transient state 136.

For additional dynamic adjustments to the variable ganging size 152, the apparatus can monitor one or more real-time conditions, as shown in block 210. The apparatus can monitor the real-time conditions, such as by accessing embedded memory, counters, sensors, indicators, and the like. For example, the memory system 102 can determine the retention measure 162, such as by accessing the P/E counter, the temperature sensor, and the like. Also, the memory system 102 (via, e.g., a preset process or software function) can analyze the performed memory operations and the corresponding commands received at the memory system 102. Based on the analysis, the memory system 102 can determine the workload measure 160 of FIG. 1.

At decision block 212, the apparatus can determine whether the real-time conditions correspond to a trigger for adjusting the scanning parameters. For example, the dynamic ganging mechanism 150 can determine the trigger condition when the workload measure 160 changes, such as to or from idle. Also, the dynamic ganging mechanism 150 can determine the trigger condition when the retention measure 162 crosses a predetermined threshold, such as for the P/E count, the device temperature, and/or the like.

When the apparatus determines that the trigger condition exists, the dynamic ganging mechanism 150 can adjust the variable ganging size 152, the scan frequency 180, or both, as shown in block 214. The dynamic ganging mechanism 150 can make the variable adjustment based on one or more predetermined processes. For example, the dynamic ganging mechanism 150 can decrease the variable ganging size 152, the scan frequency 180, or both when the workload 160 is in the idle state. Conversely, the dynamic ganging mechanism 150 can decrease the variable ganging size, the scan frequency 180, or both when the workload 160 exits from the idle state. Also, the dynamic ganging mechanism 150 can increase the variable ganging size 152, the scan frequency 180, or both when the retention measure 162 indicates decreased retentivity, such as an increase in the P/E cycle by a threshold amount or when the temperature exceeds a predetermined threshold. Conversely, the dynamic ganging mechanism 150 can decrease the variable ganging size 152, the scan frequency 180, or both when the temperature falls below the threshold.

When the apparatus does not determine the trigger condition or after adjusting the scan parameters, the apparatus can determine whether to implement the maintenance scan according to the timing, as shown in decision block 216. As described above, the memory array can fall out of the transient state 136 and back into the default stable state 134 after a known duration of inactivity. Accordingly, the dynamic ganging mechanism 150 can implement the transient scan 140 within a duration less than the known duration to maintain the array 116 in the transient state 136. The scan timing and the corresponding duration can be associated with the scan frequency 180. When the maintenance timing has not elapsed, the apparatus can take no action for the time being and continue to monitor the real-time conditions as illustrated by the feedback loop to block 210.

When the maintenance timing arrives, the apparatus can run the maintenance scan (e.g., the transient scan 140) as shown in block 218. The apparatus can implement the transient scan 140 based on the grouped reset reads 142 and according to the variable ganging size 152, such as the result of the dynamic adjustments. Also, in determining the trigger (decision block 212), the apparatus can implement the transient scan 140 and the grouped reset reads 142 according to the scan frequency 180 that results from the dynamic adjustments. After the scan, the apparatus can continue to monitor the real-time conditions, as shown by the feedback loop to block 210.

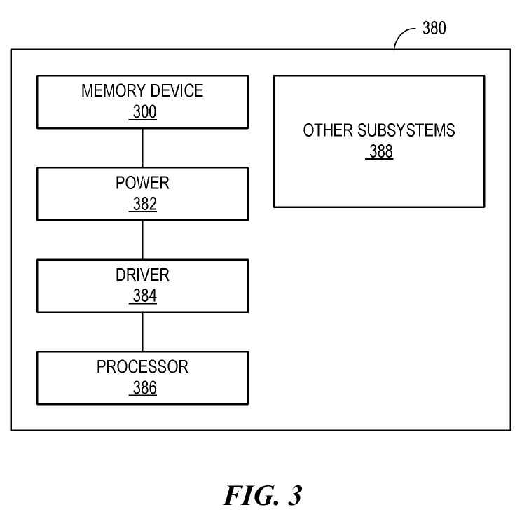

FIG. 3 is a schematic view of a system that includes an apparatus in accordance with embodiments of the present technology. Any one of the foregoing apparatuses (e.g., memory devices) described above with reference to FIGS. 1 and 2 can be incorporated into any of a myriad of larger and/or more complex systems, a representative example of which is system 380 shown schematically in FIG. 3. The system 380 can include a memory device 300, a power source 382, a driver 384, a processor 386, and/or other subsystems or components 388. The memory device 300 can include features generally similar to those of the apparatus described above with reference to one or more of the FIGS, and can therefore include various features for performing a direct read request from a host device. The resulting system 380 can perform any of a wide variety of functions, such as memory storage, data processing, and/or other suitable functions. Accordingly, representative systems 380 can include, without limitation, hand-held devices (e.g., mobile phones, tablets, digital readers, and digital audio players), computers, vehicles, appliances and other products. Components of the system 380 may be housed in a single unit or distributed over multiple, interconnected units (e.g., through a communications network). The components of the system 380 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term "processing" as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term "dynamic" as used herein describes processes, functions, actions or performance occurring during operation, usage, or deployment of a corresponding device, system or embodiment, and after or while running manufacturer's or third-party firmware. The dynamically occurring processes, functions, actions or performances can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

We claim:

1. A memory device, comprising:
a memory array including memory cells configured to store data, wherein the memory cells transition from a stable state to a transient state following a reset read operation, the transient state representing a physical state of the memory cells that corresponds to a lower error rate in providing access to the stored data; and
a logic circuit coupled to the memory array and configured to (1) implement a transient scan with a variable ganging size set to a first number of blocks in response to a power-on event, and (2) dynamically adjust the variable ganging size to a second number of blocks, different from the first number, after initially implementing the transient scan,
wherein the transient scan utilizes a set of grouped reset reads that access a number of memory blocks according to the variable ganging size and without strobing or sensing for data stored in the accessed .

2. The memory device of claim 1, wherein the first number of memory blocks for the grouped reset reads is greater than the second number.

3. The memory device of claim 2, wherein:
the initial implementation of the transient scan is configured to transition the memory cells within the memory array out of a reduced functionality phase by transitioning the memory cells into the transient state; and
the first number corresponds to a maximum number of blocks that are accessed with one function, in response to one command, across one plane, or a combination thereof.

4. The memory device of claim 3, wherein the maximum number of blocks for each implementation of the grouped reset reads is four or greater per memory plane.

5. The memory device of claim 1, wherein the logic circuit is further configured to dynamically adjust the variable ganging size set from the second number according to a workload measure that represents a type, an amount, a frequency, or a combination thereof for predicted upcoming memory operations.

6. The memory device of claim 5, wherein the logic circuit is configured to decrease the variable ganging size when the workload measure corresponds to an idle state.

7. The memory device of claim 1, wherein the logic circuit is further configured to dynamically adjust, after the initial implementation of the transient scan, the variable ganging size set according to a data retentivity measure that represents a capacity of the memory cells to provide accurate access to the stored data.

8. The memory device of claim 7, wherein the data retentivity measure corresponds to an operating temperature of the memory device.

9. The memory device of claim 8, wherein the logic circuit is configured to dynamically adjust the variable ganging size set when the operating temperature exceeds a predetermined threshold.

10. The memory device of claim 7, wherein the retentivity measure corresponds to a program-erase (P/E) count that corresponds to a number of P/E cycles performed on the memory cells.

11. The memory device of claim 10, wherein the logic circuit is configured to dynamically increase the variable ganging size set as the P/E count increases.

12. The memory device of claim 7, wherein the logic circuit is configured to increase the variable ganging size set when or as the data retentivity measure worsens.

13. A method of operating a memory device that includes memory cells configured to store data, the method comprising:
implementing an initial instance of a transient scan in response to a power-on event for transitioning the memory cells from a stable state to a transient state, the transient state representing a physical state of the memory cells that corresponds to a lower error rate than the stable state in providing access to the stored data,
wherein implementing the transient scan is implemented according to a variable ganging size set to a first number of blocks,
wherein implementing the transient scan includes reading from the memory cells with a set of grouped reset reads that accesses a number of memory blocks according to the variable ganging size and without strobing for or sensing data stored in the accessed memory blocks;
dynamically adjusting the variable ganging size to a second number of blocks, different from the first number, after initially implementing the transient scan; and
implementing a subsequent instance of the transient scan according to the second number of blocks.

14. The method of claim 13, wherein dynamically adjusting the variable ganging size includes decreasing from the first number to the second number.

15. The method of claim 14, wherein:
the initial implementation of the transient scan is configured to transition the memory cells out of a reduced functionality phase by transitioning the memory cells into the transient state; and
the first size corresponds to a maximum number of blocks that are accessed with one function, in response to one command, across one plane, or a combination thereof.

16. The method of claim 13, wherein dynamically adjusting the variable ganging size includes adjusting from a default operational size to the second number of blocks according to a real-time performance measure.

17. The method of claim 16, wherein:
the real-time performance measure includes a workload measure that represents a type, an amount, a frequency, or a combination thereof for predicted upcoming memory operations; and
adjusting from the default operational size to the second number of blocks includes decreasing the variable ganging size when the workload measure corresponds to an idle state.

18. The method of claim 16, wherein:
the real-time performance measure includes a data retentivity measure that represents a capacity of the memory cells to provide accurate access to the stored data; and
adjusting from the default operational size to the second number of blocks includes increasing the variable ganging size set when or as the data retentivity measure worsens.

19. The method of claim 18, wherein:
the data retentivity measure corresponds to an operating temperature of the memory device; and
adjusting from the default operational size to the second number of blocks includes increasing the variable ganging size set while the operating temperature remains above an operating temperature range.

20. The method of claim 18, wherein:
the data retentivity measure corresponds to a program-erase (P/E) count that corresponds to a number of P/E cycles performed on the memory cells; and
adjusting from the default operational size to the second number of blocks includes increasing the variable ganging size set as the P/E count increases.
